(19) United States
(12) Patent Application Publication
(10) Pub. No.: US 2011/0048523 A1
(43) Pub. Date: Mar. 3, 2011

(54) DYE-SENSITIZED SOLAR CELL

(75) Inventors: Sang-Yeol HUR, Suwon-si (KR); Ji-Won Lee, Suwon-si (KR); Jong-Ki Lee, Suwon-si (KR); Moon-Sung Kang, Suwon-si (KR); Byong-Cheol Shin, Suwon-si (KR); Nam-Choul Yang, Suwon-si (KR); Hyun-Chul Kim, Suwon-si (KR); Si-Young Cha, Suwon-si (KR); Do-Young Park, Suwon-si (KR)

(73) Assignee: Samsung SDI Co., Ltd., Suwon-si (KR)

(21) Appl. No.: 12/691,161

(22) Filed: Jan. 21, 2010

(30) Foreign Application Priority Data
Aug. 26, 2009 (KR) 10-2009-0079315

(51) Int. Cl. H01L 31/00

(52) U.S. Cl. 136/256

(57) ABSTRACT

Provided is a dye-sensitized solar cell including a first substrate and a second substrate facing each other; a first electrode unit and a second electrode unit disposed between the first substrate and the second substrate and respectively including at least one or more grid electrodes; an electrolyte filled in the first electrode unit and the second electrode unit; a sealing material for sealing the electrolyte between the first substrate and the second substrate; a collector electrode unit including a first collector electrode and a second collector electrode electrically connected to the first electrode unit and the second electrode unit, respectively; and a protruding terminal unit including a first protruding terminal and a second protruding terminal electrically connected to the first collector electrode and the second collector electrode, respectively. At least a portion of at least one of the collector electrodes is disposed in an internal area sealed by the sealing material, and the first electrode unit includes an oxide layer including dye molecules.

### CROSS-REFERENCE TO RELATED APPLICATION

This application claims the benefit of Korean Patent Application No. 10-2009-0079315, filed Aug. 26, 2009 in the Korean Intellectual Property Office, the disclosure of which is incorporated herein in its entirety by reference.

### BACKGROUND

1. Field

One or more embodiments of the present invention relate to a dye-sensitized solar cell, and more particularly, to a dye-sensitized solar cell which includes a collector electrode.

2. Description of the Related Art

Recently, in order to solve energy-related problems, various studies have been conducted to substitute existing fossil fuels. In particular, in order to substitute oil resources that are to be exhausted within decades, a wide range of studies have been conducted on how to use natural energies. Examples include the use of wind power, atomic power, solar power, or the like. In this regard, a solar cell using solar energy has been highlighted in recently since, unlike other energy sources, the source of solar energy is unlimited and solar energy is environmentally friendly.

From among various types of solar cells, a silicon solar cell is in highlight. Since the silicon solar cell is very expensive due to high manufacturing costs, it is difficult to commercialize the silicon solar cell and to improve its efficiency. In order to overcome the aforementioned problems, the silicon solar cell has been positively examined to develop a dye-sensitized solar cell that has considerably lower manufacturing costs.

Unlike the silicon solar cell, the dye-sensitized solar cell is a photo-electro-chemical solar cell. The dye-sensitized solar cell is formed of photosensitive dyes capable of absorbing visible light and generating electron-hole pairs, and a transition metal oxide for delivering the generated electron. This dye-sensitized solar cell has drawn great attention in that the photo-electro-chemical solar cell can substitute a silicon solar cell since the dye-sensitized solar cell can be manufactured at lower costs per unit of power, as compared with the silicon solar cell.

### SUMMARY

According to one or more embodiments of the present invention, a dye-sensitized solar cell includes a first substrate and a second substrate facing each other; a first electrode unit and a second electrode unit disposed between the first substrate and the second substrate and respectively including at least one or more grid electrodes; an electrolyte filled in the first electrode unit and the second electrode unit; a sealing material for sealing the electrolyte between the first substrate and the second substrate; a collector electrode unit including a first collector electrode and a second collector electrode electrically connected to the first electrode unit and the second electrode unit, respectively; and a protruding terminal unit including a first protruding terminal and a second protruding terminal electrically connected to the first collector electrode and the second collector electrode, respectively, wherein at least a portion of at least one of the collector electrodes is disposed in an internal area sealed by the sealing material, and the first electrode unit comprises an oxide layer comprising dye molecules.

According to an aspect of the invention, the protruding terminal unit may protrude in a direction orthogonal to a direction in which the collector electrode unit extends.

According to an aspect of the invention, protruding terminal unit that is connected to the collector electrode unit disposed in the internal area sealed by the sealing material may cross the sealing material and is electrically connected to an outside.

According to an aspect of the invention, at least one selected from among the group consisting of the first electrode unit, the second electrode unit, the collector electrode unit, and the protruding terminal unit may further include a protective layer.

According to an aspect of the invention, at least one of the grid electrodes may have a wider line width than that of the other ones.

According to an aspect of the invention, the grid electrode having the wider line width may be electrically connected to the collector electrode unit so as to correspond to the protruding terminal unit.

According to an aspect of the invention, the number of the protruding terminals of the protruding terminal unit may be less than the number of the grid electrodes.

According to an aspect of the invention, a line width of the first protruding terminal or the second protruding terminal of the protruding terminal unit may be wider than that of the collector electrode unit.

According to an aspect of the invention, a line width of the first collector electrode or the second collector electrode of the collector electrode unit may be wider than that of the grid electrodes.

According to an aspect of the invention, the protruding terminal unit may be enabled to be directly connected to another protruding terminal unit of another dye-sensitized solar cell.

Additional aspects will be set forth in part in the description which follows and, in part, will be apparent from the description, or may be learned by practice of the exemplary embodiments.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a diagram for describing an operating principle of a general dye-sensitized solar cell;

FIG. 2 is a perspective view of a basic structure of the general dye-sensitized solar cell of FIG. 1;

FIG. 3 is a cross-sectional view of the general dye-sensitized solar cell of FIG. 1, taken along a line III-III in FIG. 2;

FIG. 4 is an exploded perspective view of a structure of a dye-sensitized solar cell with a protruding terminal formed at one side of the dye-sensitized solar cell, according to an embodiment of the present invention;

FIG. 5 is a top-plan view of the dye-sensitized solar cell in FIG. 4;

FIG. 6 is a cross-sectional view of the dye-sensitized solar cell, taken along a line VI-VI in FIG. 5;

FIG. 7 is a cross-sectional view of the dye-sensitized solar cell, taken along a line VII-VII in FIG. 5;

FIG. 8 is a cross-sectional view of the dye-sensitized solar cell, taken along a line VIII-VIII in FIG. 5;

FIG. 9 is a plan view of a structure of a dye-sensitized solar cell with protruding terminal units formed at both sides of the dye-sensitized solar cell, according to an embodiment of the present invention;

FIG. 10 is a plan view of a dye-sensitized solar cell having a similar structure to the structure in FIG. 9, according to an embodiment of the present invention, in which one or more grid electrodes have line widths that are not equal to each other;

FIG. 11 is a plan view of a structure of a dye-sensitized solar cell formed by serially connecting dye-sensitized solar cells as the one in FIG. 10;

FIG. 12 is a top-plan view of a structure of a dye-sensitized solar cell in which a portion of a collector electrode is disposed through a sealing material, according to an embodiment of the present invention; and

FIG. 13 is a top-plan view of a structure of a dye-sensitized solar cell having third protruding terminals with a modified shape, according to an embodiment of the present invention.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

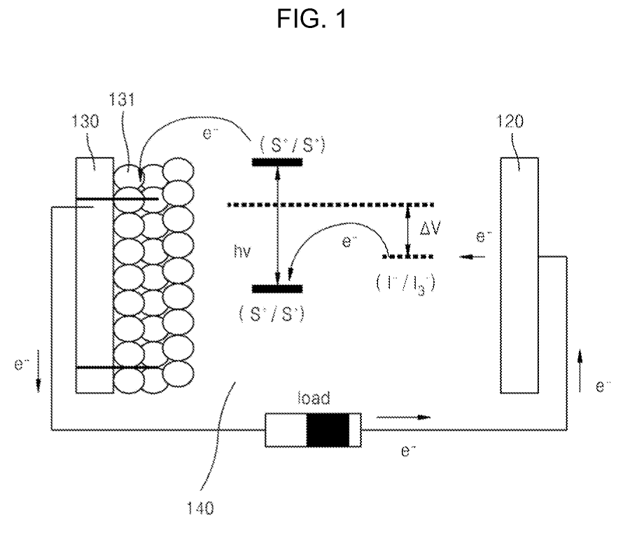

FIG. 1 is a diagram for describing an operating principle of a general dye-sensitized solar cell. The general dye-sensitized solar cell operates in the following manner. When solar rays are absorbed in dye-sensitized solar cell, photons with sufficient energy hit dye molecules (not shown) on a surface of an oxide layer 131. The dye molecules turn to an exited state and emit electrons e−. The electrons e− emitted from the dye molecules generate electricity while moving according to a chemical diffusion gradient. The dye molecules are photosensitive dye molecules capable of absorbing visible light and generating electron-hole pairs. In addition, each of the dye molecules is very small, and thus, in order to contain a large number of dye molecules, the oxide layer 131 is used as a scaffold for the dye molecules.

Referring to FIG. 1, the dye molecules turn to the excited state (S+/S*) from a ground state (S+/S), and the excited dye molecules are oxidized by emitting the electrons e−. The oxidized dye molecules are reduced by receiving electrons e− from iodine ions in an oxidation-reduction electrolyte (I−/I 3−) disposed between a semiconductor electrode 130 and a counter electrode 120 formed of platinum, and the iodine ions are oxidized. Meanwhile, the excited electrons e− are injected into a conduction band of the oxide layer 131, and transferred to the counter electrode 120 via the semiconductor electrode 130 and an external circuit (not shown). The electrons e− that reach the counter electrode 120 reduce the oxidized iodine ions. In this manner, by absorbing the solar rays, the general dye-sensitized solar cell induces a transfer of the electrons e−. That is, the general dye-sensitized solar cell induces a flow of current, thereby functioning as a solar cell.

The general dye-sensitized solar cell is sealed with a sealing material so an electrolyte does not leak. In this regard, since the semiconductor electrode 130 and the counter electrode 120 are connected to the outside via the sealing material, there is a chance that the electrolyte may leak at an intersection portion between the sealing material and the semiconductor electrodes 130 or between the sealing material and the counter electrode 120.

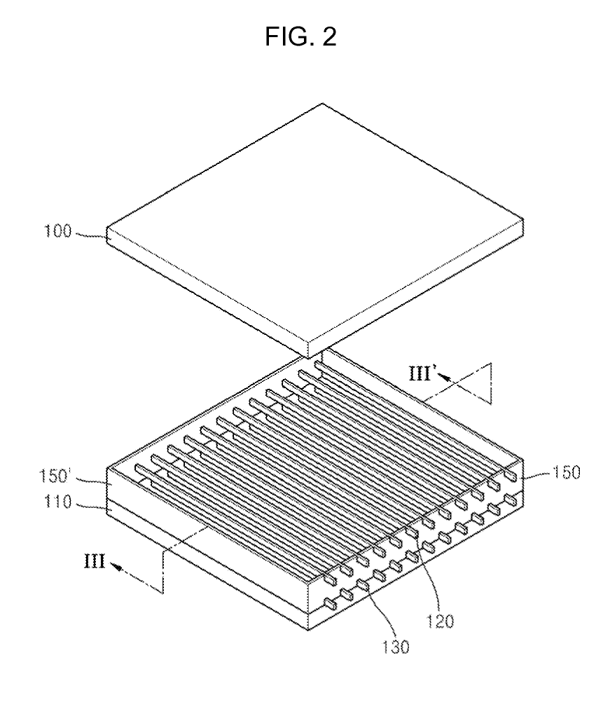

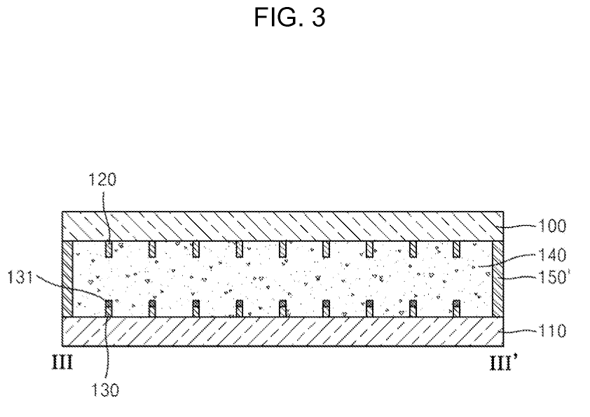

FIG. 2 is a perspective view of a basic structure of the general dye-sensitized solar cell of FIG. 1. FIG. 3 is a cross-sectional view of the general dye-sensitized solar cell of FIG. 1, taken along a line III-III in FIG. 2. Referring to FIG. 2 and FIG. 3, the general dye-sensitized solar cell includes a first substrate 100, a second substrate 110, the counter electrode 120, the semiconductor electrode 130, the oxide layer 131, an electrolyte 140, and first and second sealing materials 150 and 150′. The counter electrode 120 may be formed with a platinum thin film that is adhered thereto as a catalyst for the electrolyte 140 so as to boost reduction and to improve reflectivity of solar rays. The semiconductor electrode 130 functions to enable absorption of solar energy and to transfer electrons to an external circuit (not shown). Dye molecules (not shown) absorb the solar energy of visible light and generate electron-hole pairs. The oxide layer 131 absorbs the dye molecules so as to deliver the electrons that are generated in the dye molecules. The electrolyte 140 functions to reduce the oxidized dye molecules. The first sealing material 150 seals the first and second substrates 100, 110 to prevent the electrolyte 140 between the first substrate 100 and the second substrate 110 from leaking. Here, the counter electrode 120 and/or the semiconductor electrode 130 is connected to the outside via the first sealing material 150. In this regard, if a plurality of the counter electrodes 120 and/or a plurality of the semiconductor electrodes 130 pass through the first sealing material 150 at one time, the first sealing material 150 does not evenly seal the plurality of counter electrodes 120 and/or the plurality of the semiconductor electrodes 130. Thus there is a high chance that the electrolyte 140 may leak past the material 150 at the intersection with the electrodes 120, 130. In addition, the second sealing material 150′ seals in a longitudinal direction of the counter electrode 120 and/or the semiconductor electrode 130, so as to prevent the electrolyte 140 between the first substrate 100 and the second substrate 110 from leaking.

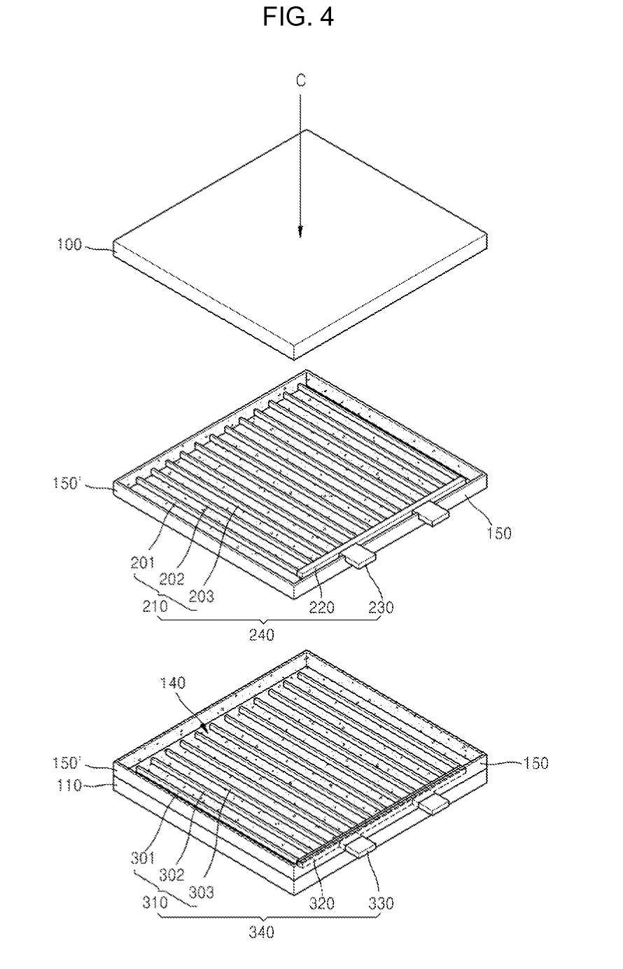

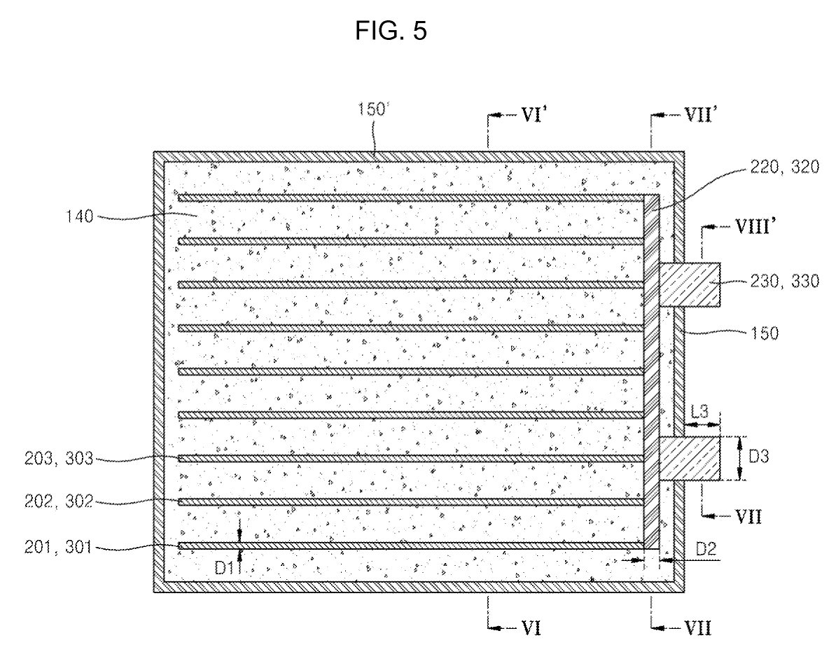

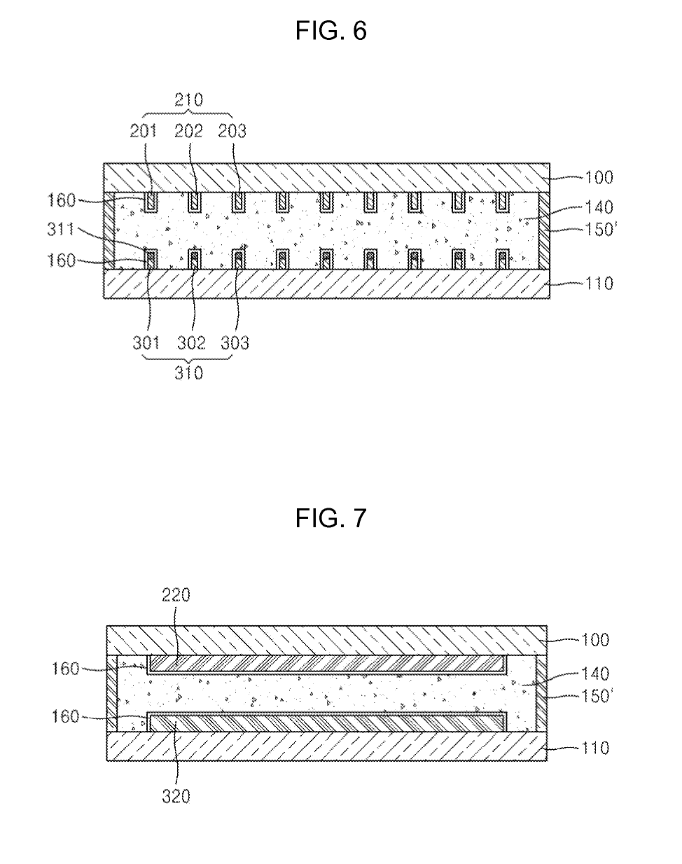

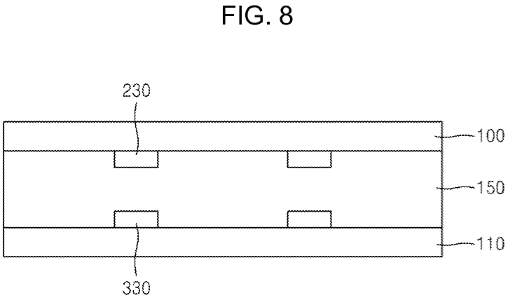

FIG. 4 is an exploded perspective view of a structure of a dye-sensitized solar cell with a protruding terminal 230 formed at one side of the dye-sensitized solar cell so as to decrease a leak possibility of the electrolyte 140, according to an embodiment of the present invention. FIG. 5 is a top-plan view of the dye-sensitized solar cell in FIG. 4. FIG. 6 is a cross-sectional view of the dye-sensitized solar cell, taken along a line VI-VI′ in FIG. 5. FIG. 7 is a cross-sectional view of the dye-sensitized solar cell, taken along a line VII-VII′ in FIG. 5. FIG. 8 is a cross-sectional view of the dye-sensitized solar cell, taken along a line VIII-VIII′ in FIG. 5.

Referring to FIGS. 4 through 8, the dye-sensitized solar cell includes the first substrate 100, the second substrate 110, a first oxide layer 311, dye molecules (not shown), the electrolyte 140, the first and second sealing materials 150 and 150′, a protective layer 160, a first counter electrode 240, and a first semiconductor electrode 340. As shown, the first substrate 100, the second substrate 110, the first oxide layer 311, and the electrolyte 140 have generally the same functions and operate in the same manner as the first substrate 100, the second substrate 110, the oxide layer 131, and the electrolyte layer 140 described with reference to FIG. 2 and FIG. 3. Referring to FIG. 4, the first substrate 100 is disposed in a direction C of an incident light relative to the second substrate 110 so as to be closest to the incident light.

The first counter electrode 240 includes a counter grid electrode unit 210, a counter collector electrode 220, and a counter protruding terminal unit 230. The counter grid electrode unit 210 comprises a plurality of counter grid electrodes 201, 202, 203. The first semiconductor electrode 340 includes a semiconductor grid electrode unit 310, a semiconductor collector electrode 320, and a semiconductor protruding terminal unit 330. The semiconductor grid electrode unit 310 comprises a plurality of semiconductor grid electrodes 301, 302, 303. While shown with two counter terminal units 230 and two semiconductor terminal units 330, it is understood that other numbers can be used.

Although the first semiconductor electrode 340 further includes the first oxide layer 311, compared with the first counter electrode 240, a structural connection of the semiconductor grid electrodes unit 310, the semiconductor collector electrode 320, and the semiconductor protruding terminal unit 330 may be similar to that of the counter grid electrode unit 210, the counter collector electrode 220, and the counter protruding terminal unit 230 of the first counter electrode 240. Thus, for convenience of description, the structure of the first counter electrode 240 will be mainly described with reference to FIGS. 5 through 8. Referring to FIG. 5, the first counter electrode 240 includes the counter collector electrode 220 disposed inside the first and second sealing materials 150 and 150′ and to which the counter grid electrodes 201, 202, 203 are commonly connected. Referring to FIG. 6, the counter grid electrode unit 210 is disposed between the first substrate 100 and the second substrate 110 and connects to the first substrate 100. Such counter grid electrodes 201, 202, 203 extend in a longitudinal direction and are all connected to the counter collector electrode 220.

FIG. 7 illustrates a cross-section of the counter collector electrode 220. Referring to FIG. 7, the counter collector electrode 220 is disposed inside the first and second sealing materials 150 and 150′ while the counter grid electrodes 201, 202, 203 are commonly connected thereto. Since the counter collector electrode 220 is disposed inside the first and second sealing materials 150 and 150′, the dye-sensitized solar cell further includes the counter protruding terminal unit 230 for electrical connection with the outside, such as a load.

The first and second sealing materials 150 and 150′ may include a thermoplastic polymer material such as Surlyn 1702 available from DuPont Company.

The counter protruding terminal unit 230 extends through the first sealing material 150 and has a side connected to the counter collector electrode 220, and another side electrically connected to the outside as illustrated in FIG. 5. The shown number of counter protruding terminal units 230 is less than that of the counter grid electrodes 201, 202, 203 of the counter grid electrode unit 210. In this manner, by disposing the counter collector electrode 220 in the first and second sealing materials 150 and 150′, a large number of counter grid electrodes 201, 202, 203 are not connected to the outside by extending through the first sealing material 150, but the counter protruding terminal units 230 that are less in number than the number of counter grid electrodes 201, 202, 203 are electrically connected to the outside and extends through the first sealing material 150. Thus, a total number of elements passing through the first sealing material 150 is decreased, which decreases a possibility that the electrolyte 140 may leak via the first sealing material 150 due to a defective seal.

While not required in all aspects, the first counter electrode 240 and the first semiconductor electrode 340 include the protective layer 160. The protective layer 160 prevents the electrode 240, 340 from being corroded by the electrolyte 140. The protective layer 160 may be formed as a dielectric layer formed of a glass material. Also, the protective layer 160 may be formed of Surlyn. In addition, the protective layer 160 is formed on the first counter electrode 240 or the first semiconductor electrode 340 disposed inside the first and second sealing materials 150 and 150′. Thus, the layer 160 may prevent the counter collector electrode 220 or the semiconductor collector electrode 320 from being damaged when the electrolyte 140 is injected. The protective layer 160 may cross the first and second sealing materials 150 and 150′ so as to be formed on the counter protruding terminal unit 230 and the semiconductor protruding terminal unit 330 that are connected to the outside as shown in FIG. 7.

While not required in all aspects, referring to FIG. 5, a line width D2 of the counter collector electrode 220 is formed to be wider than a line width D1 of each counter grid electrode 201, 202, 203 of the counter grid electrode unit 210. Having such wider line widths facilitates a flow of current generated in the counter grid electrodes 201, 202, 203. That is, the larger the cross-sectional area of an electrode is, the smaller the electrical resistance is, whereby the flow of the current may be facilitated.

While not required in all aspects, a line width D3 of the counter protruding terminal unit 230 is formed to be greater than the line width D2 of the counter collector electrode 220. By doing so, an amount of current that flows in the counter collector electrode 220 may increase by enlarging the line width D3 of the counter protruding terminal unit 230.

The dye-sensitized solar cell may be embedded in various structures; however, in the case where the dye-sensitized solar cell is attached to a glass window and used, the counter protruding terminal unit 230 disposed at the edges of the dye-sensitized solar cell may be disposed to correspond to a frame of the glass window to less affect an aperture ratio.

Here, the line width D2 of the counter collector electrode 220 may be from about 500 μm to about 6 mm, and the line width D3 of the counter protruding terminal unit 230 may be from about 0.5 mm to about 5 mm. Also, a length L3 from the first sealing material 150 to an end of the counter protruding terminal unit 230 may be from about 0.5 mm to about 1.5 mm. However, the line width D2 of the counter collector electrode 220, the line width D3 of the counter protruding terminal unit 230, and the length L3 of the counter protruding terminal unit 230 are not limited thereto, and thus may vary.

Here, the counter protruding terminal units 230 may have structures to be interconnected. Thus, the counter protruding terminal units 230 facing each other may be electrically interconnected or may be structurally combined with each other.

The first semiconductor electrode 340 may be formed in a similar manner to the first counter electrode 240. That is, the first semiconductor electrode 340 includes the plurality of semiconductor grid electrodes 301, 302, 303 forming semiconductor grid electrode unit 310; the semiconductor collector electrode 320; and the semiconductor protruding terminal unit 330. Referring to FIGS. 4 through 8, the semiconductor collector electrode 320 is disposed inside the first and second sealing materials 150 and 150′. Since the semiconductor collector electrode 320 is disposed inside the first sealing material 150, the dye-sensitized solar cell further includes the semiconductor protruding terminal unit 330 for electrical connection with the outside. The number of the semiconductor protruding terminal unit 330 is less than that of the semiconductor grid electrodes 301, 302, 303 of the semiconductor grid electrode unit 310. Since the number of the semiconductor protruding terminal unit 330 is less than that of the semiconductor grid electrodes 301, 302, 303, the number of elements passing through the first sealing material 150 decreases, which decreases a possibility that the electrolyte 140 may leak via the first sealing material 150 due to a defective seal. Line widths and lengths of the semiconductor grid electrodes 301, 302, 303, the semiconductor collector electrode 320, and the semiconductor protruding terminal unit 330 may be substantially the same as those of the counter grid electrodes 201, 202, 203, the counter collector electrode 220, and the counter protruding terminal unit 230, respectively. However, the invention is not limited thereto.

As described above, the counter collector electrode 220 of the first counter electrode 240 is disposed inside the first and second sealing materials 150 and 150′, and the semiconductor collector electrode 320 of the first semiconductor electrode 340 is disposed inside the first and second sealing materials 150 and 150′. However, the present embodiment may not be limited thereto. For example, the counter collector electrode 220 of the first counter electrode 240 or the semiconductor collector electrode 320 of the first semiconductor electrode 340 may be disposed inside the first and second sealing materials 150 and 150′.

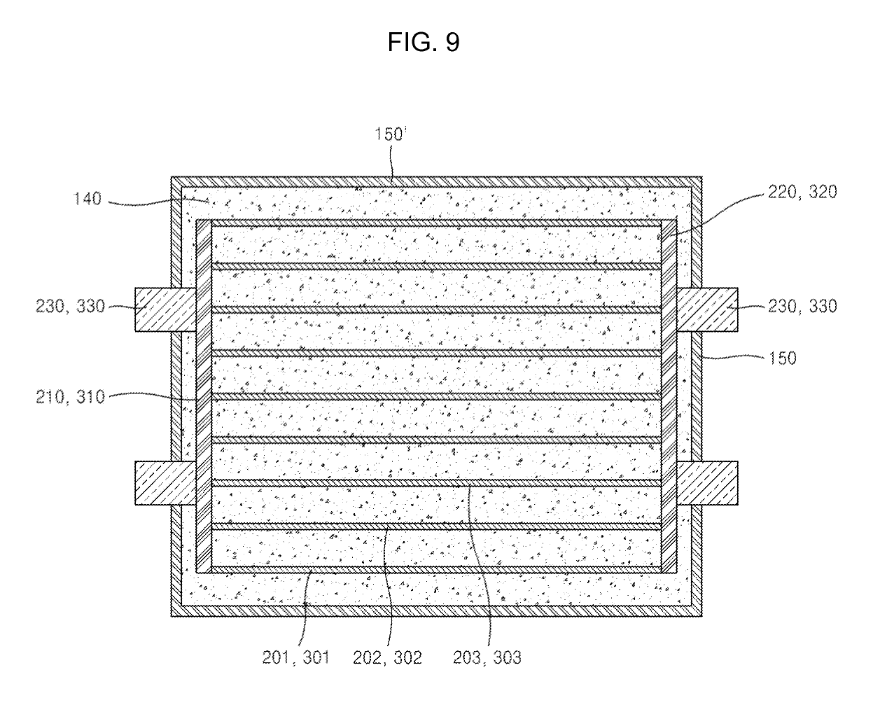

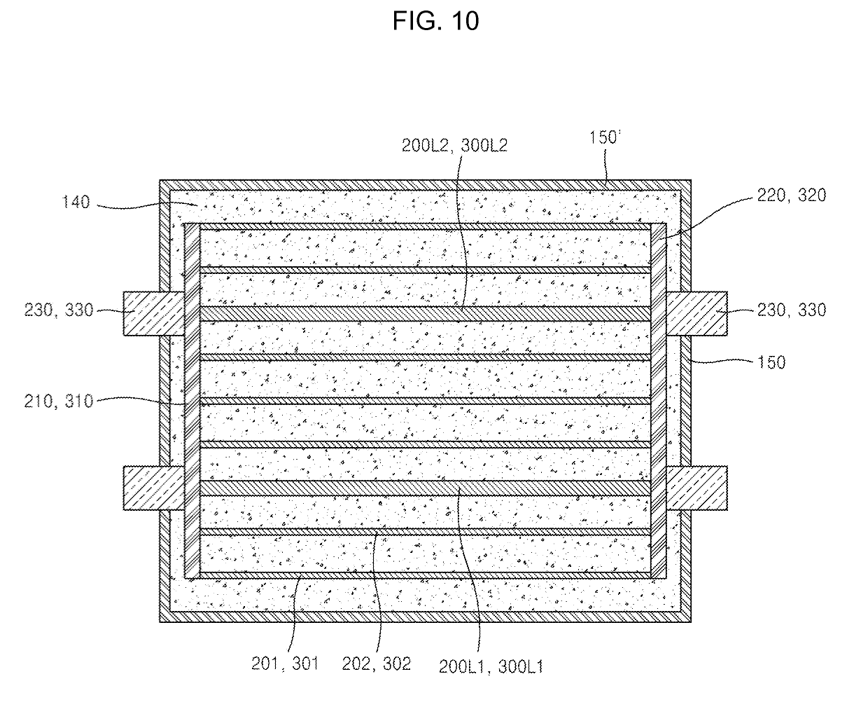

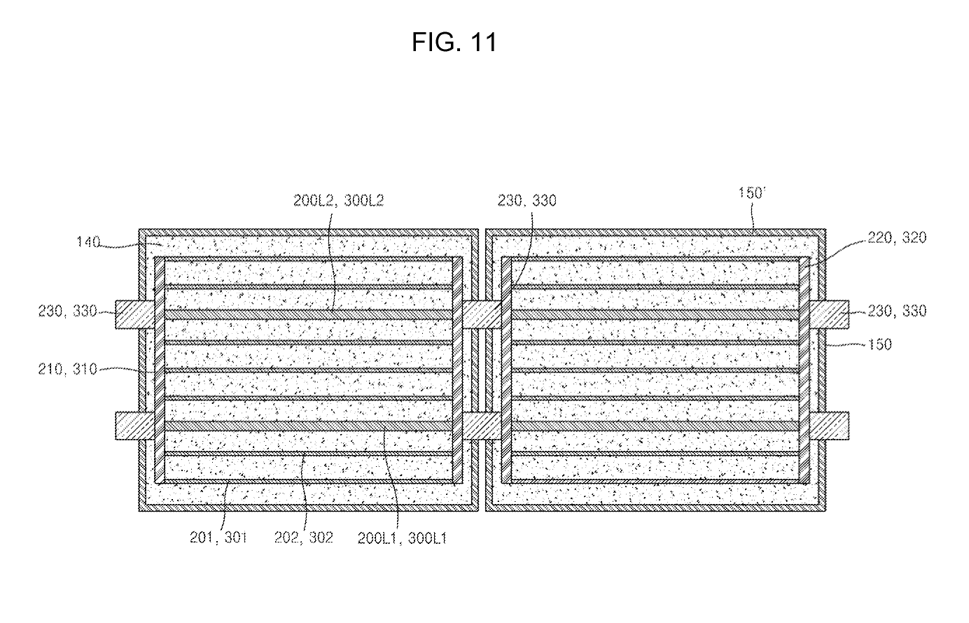

FIG. 9 is a plan view of a structure of a dye-sensitized solar cell with protruding terminal units 230 and 330 formed at both sides of the dye-sensitized solar cell, according to an embodiment of the present invention. FIG. 10 is a plan view of a dye-sensitized solar cell having a similar structure to the structure in FIG. 9, according to an embodiment of the present invention, in which one or more grid electrodes 201, 202, 203, 301, 302, 303 have line widths that are not equal to each other. FIG. 11 is a plan view of a structure of a dye-sensitized solar cell formed by serially connecting dye-sensitized solar cells as the one in FIG. 10.

Referring to FIG. 9, the dye-sensitized solar cell includes the protruding terminal units 230 and 330 that are formed at both sides of the dye-sensitized solar cell. Other than these elements, the rest of the elements are the same as those of the dye-sensitized solar cell of FIG. 4. That is, the first counter electrode 240 includes the counter grid electrode unit 210, the counter collector electrode 220, and the counter protruding terminal unit 230, and the first semiconductor electrode 340 includes the semiconductor grid electrode unit 310, the semiconductor collector electrode 320, and the semiconductor protruding terminal unit 330. In the shown embodiment, since the protruding terminal units 230 and 330 are connected to both sides of the dye-sensitized solar cell, it is possible to electrically connect the protruding terminal units 230 and 330 and to facilitate the structural connection between dye-sensitized solar cells. That is, when a large number of the dye-sensitized solar cells are connected, the dye-sensitized solar cells may be electrically connected in series without using a separate connecting component therebetween.

Also, as illustrated in FIG. 10, it is possible to form the dye-sensitized solar cell including one or more electrodes 200L1, 300L1 and 200L2, 300L2 having a line width greater than that of other grid electrodes 201, 301, 202, 302. FIG. 11 illustrates the structure of the dye-sensitized solar cell formed by serially connecting dye-sensitized solar cells each as the one in FIG. 10, and in this regard, as the number of dye-sensitized solar cells increases, an amount of generated current increases and also, a loss of the current increases in proportion to the square of the current according to Equation 1.

p=I²R (where, p indicates a power loss, I indicates current, and R indicates resistance) Equation 1

In order to decrease the power loss, one or more grid electrodes 200L1, 300L1 and 200L2, 300L2 may have a line width greater than that of other grid electrodes 201, 301, 202, 302. By having the greater line width, a cross-sectional area whereon the current flows increases so that an electrical resistance may decrease. In other words, when the amount of current flowing in the dye-sensitized solar cells increases by connecting the dye-sensitized solar cells, it is possible to offset the power loss by allowing one or more grid electrodes 200L1, 300L1 and 200L2, 300L2 to have the line width greater than that of other grid electrodes 201, 301, 202, 302.

As shown, the grid electrodes 200L1, 300L1 and 200L2, are electrically connected to the counter collector electrode 220 and the semiconductor collector electrode 320, respectively, so as to face the counter protruding terminal unit 230 and the semiconductor protruding terminal unit 330.

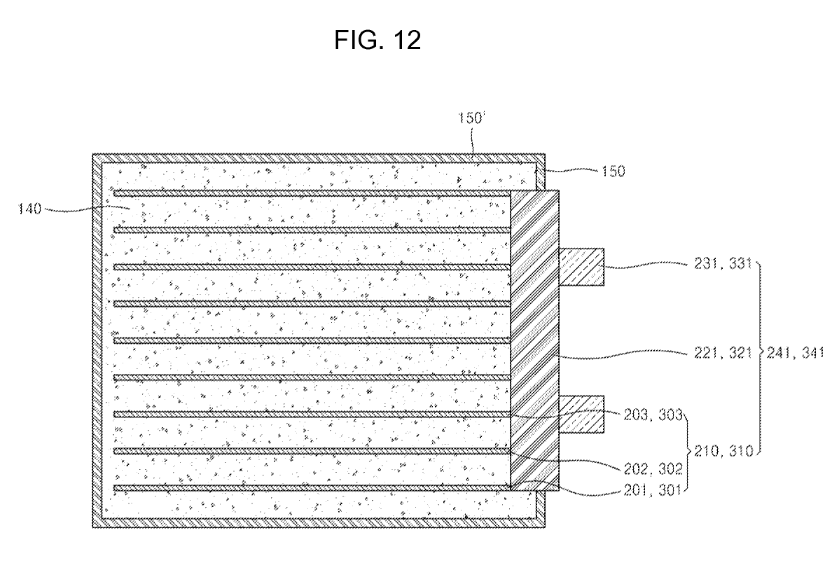

FIG. 12 is a top-plan view of a structure of a dye-sensitized solar cell in which a portion of the collector electrode 221, 231 is disposed extending through the sealing material 150, according to an embodiment of the present invention. Referring to FIG. 12, the dye-sensitized solar cell includes counter and semiconductor grid electrode units 210 and 310, second collector electrodes 221 and 321, and protruding terminals 231 and 331. Here, a structure of the counter and semiconductor grid electrode units 210 and 310 is the same as that of the counter and semiconductor grid electrode units 210 and 310 of the dye-sensitized solar cell of FIGS. 4 through 6. According to the present embodiment of FIG. 12, portions of the collector electrode 221, 231 are disposed inside the first and second sealing materials 150 and 150′, and simultaneously, other portions of the collector electrode 221, 231 are electrically connected to the outside by passing through the first sealing material 150. The protruding terminals 231 and 331 are connected to the portion of the collector electrode 221, 231 extending outside of the first sealing material 150, while the counter and semiconductor grid electrode units 210 and 310 are connected to the portion of the collector electrode 221, 231 inside the first sealing material 150.

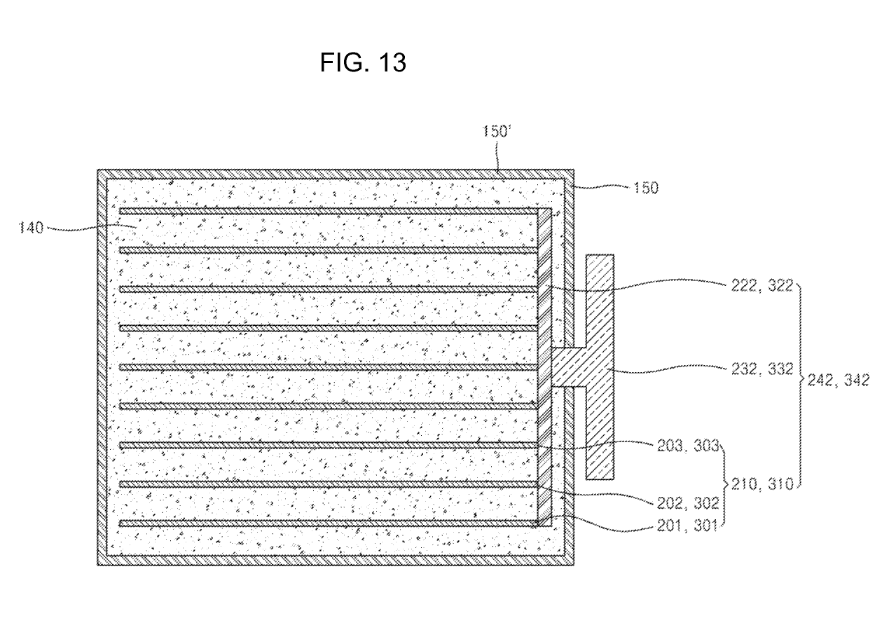

FIG. 13 is a top-plan view of a structure of a dye-sensitized solar cell having third protruding terminals 232 and 332 with a modified shape, according to an embodiment of the present invention. Referring to FIG. 13, the dye-sensitized solar cell includes grid electrode units 210 and 310, third collector electrodes 222 and 322, and the third protruding terminals 232 and 332. A structure of the grid electrode units 210 and 310 is the same as that of the counter and semiconductor grid electrode units 210 and 310 of the dye-sensitized solar cell of FIGS. 4 through 6. According to the present embodiment of FIG. 13, the third collector electrodes 222 and 322 are disposed inside the first and second sealing materials 150 and 150′, and the third protruding terminals 232 and 332 extend through the first sealing material 150 and are connected to the outside. As illustrated in FIG. 13, the third protruding terminals 232 and 332 has a T shape in which a bottom portion of the T shape extends through the sealing material 150 and connects to the third collector electrodes 222, 322, and the top portion of the T shape is disposed outside of the sealing material 150 so as to be directly connected to another dye-sensitized solar cell in another module. However, while described in terms of a T shape, it is understood that other shapes can be used and varied according to the external device to which the cell is being connected.

It should be understood that the exemplary embodiments described therein should be considered in a descriptive sense only and not for purposes of limitation. Descriptions of features or aspects within each embodiment should typically be considered as available for other similar features or aspects in other embodiments. Further, it would be appreciated by those skilled in the art that changes may be made in this embodiment without departing from the principles and spirit of the invention, the scope of which is defined in the claims and their equivalents.

1. A dye-sensitized solar cell comprising:
a first substrate;
a second substrate facing the first substrate;
a first electrode unit and a second electrode unit disposed between the first substrate and the second substrate, each of the first and second electrode units comprising grid electrodes;
an electrolyte filled in the first electrode unit and the second electrode unit;
a sealing material which seals the electrolyte between the first substrate and the second substrate;
a collector electrode unit comprising a first collector electrode electrically connected to the first electrode unit and a second collector electrode electrically connected to the second electrode unit; and
a protruding terminal unit comprising a first protruding terminal electrically connected to the first collector electrode and a second protruding terminal electrically connected to the second collector electrode,
wherein:
at least a portion of at least one of the first and second collector electrodes is disposed in an internal area sealed by the sealing material, and
the first electrode unit comprises an oxide layer comprising dye molecules.

2. The dye-sensitized solar cell of claim 1, wherein the protruding terminal unit protrudes through the sealing material in a direction orthogonal to a direction in which the collector electrode unit extends.

3. The dye-sensitized solar cell of claim 1, wherein the one protruding terminal unit extends through the sealing material and is electrically connectable to an outside load.

4. The dye-sensitized solar cell of claim 1, wherein at least one of the first electrode unit, the second electrode unit, the collector electrode unit, and the protruding terminal unit further comprises a protective layer.

5. The dye-sensitized solar cell of claim 1, wherein, for one of the first and second electrode units, at least one of the grid electrodes has a line width which is wider than a line width of the other ones of the grid electrodes.

6. The dye-sensitized solar cell of claim 5, wherein the grid electrode having the wider line width is electrically connected to the collector electrode unit at a location near a connection between the collector electrode unit and the protruding terminal unit.

7. The dye-sensitized solar cell of claim 1, wherein a number of the protruding terminals of the protruding terminal unit extending through the seal is less than a number of the grid electrodes.

8. The dye-sensitized solar cell of claim 1, wherein a line width of the first protruding terminal or the second protruding terminal of the protruding terminal unit is wider than a line width of the collector electrode unit.

9. The dye-sensitized solar cell of claim 1, wherein a line width of the first collector electrode or the second collector electrode of the collector electrode unit is wider than a line width of the grid electrodes.

10. The dye-sensitized solar cell of claim 1, wherein the protruding terminal unit is shaped to be directly connected to another protruding terminal unit of another dye-sensitized solar cell.

11-12. (canceled)

13. The dye-sensitized solar cell of claim 1, wherein:
a direction of the grid electrodes is substantially the same as a direction of the first protruding terminal, and
a direction of the first collector electrode is substantially different from the direction of the grid electrodes.

14. (canceled)

15. The dye-sensitized solar cell of claim 1, wherein the first collector electrode extends through the sealing material and has a first connection portion electrically connected to the grid electrodes, second connection portion electrically connected to the first protruding terminal, and the sealing material forms a seal on the first collector electrode at a location between the first and second connection portions of the first collector electrode.

16. The dye-sensitized solar cell of claim 1, wherein at least one of the first and second protruding terminals have a T shape.

17. The dye-sensitized solar cell of claim 16, wherein a top portion of the T shape is shaped connectable to an external device.

18. The dye-sensitized solar cell of claim 16, wherein a bottom portion of the T shape is extends through the sealing material.

19. (canceled)

20. The dye-sensitized solar cell of claim 1, wherein each of the grid electrodes has a same line width.
